(19) United States
(12) Patent Application Publication
(10) Pub. No.: US 2025/0148152 A1
(43) Pub. Date: May 8, 2025

(54) AUTO-GENERATION OF SIMULATION DEVICES FOR A HARDWARE-IN-THE-LOOP SIMULATION

(71) Applicant: Disney Enterprises, Inc., Burbank, CA (US)

(72) Inventors: Gregory J. NATHAN, Orlando, FL (US); Rich GRGIC, Concord Township, OH (US); Cecelia DAHLINGER, Winter Garden, FL (US); Matthew J. STRANDSKOV, Ocoee, FL (US); Brian Foster WALTERS, Groveland, FL (US); Faith Elizabeth Smith HASLEBACHER, Clermont, FL (US)

(73) Assignee: Disney Enterprises, Inc., Burbank, CA (US)

(21) Appl. No.: 18/501,159

(22) Filed: Nov. 3, 2023

(51) Int. Cl. G06F 30/17

(52) U.S. Cl. CPC G06F 30/17

(57) ABSTRACT

An HIL simulation platform may analyze a computer-aided design (CAD) drawing of a device of an operator console. The HIL simulation platform may determine, based on analyzing the CAD drawing, device type information and signal information of the device. The device type information identifies a device type of the device and the signal information identifies one or more signal types of signals associated with the device. The HIL simulation platform may generate, based on the device type information, a simulation device for an HIL simulation of an operation of the device in an HIL simulation environment. The HIL simulation platform may generate, based on the signal information, a name of an output signal from the simulation device. The HIL simulation platform may map, based on the name, the output signal to a controller device in a real world environment and execute a computer model to perform the HIL simulation.

### BACKGROUND

Hardware-in-the-loop (HIL) simulations are used in the development and test of complex real-time control systems. HIL simulations involve simulating multiple systems of a controlled environment to provide realistic inputs to a controller being developed or under test. Each external system that communicates with the controller is implemented by a mathematical representation (e.g., a software application) that produces signals and values that simulate the real-time controlled environment.

### SUMMARY

In some implementations, a method performed by an HIL simulation platform includes analyzing a computer-aided design (CAD) drawing of a device of an operator console; determining, based on analyzing the CAD drawing, device type information and signal information of the device, wherein the device type information identifies a device type of the device, and wherein the signal information identifies one or more signal types of signals associated with the device; generating, based on the device type information, a simulation device for an HIL simulation of an operation of the device in an HIL simulation environment; generating, based on the signal information, a name of an output signal from the simulation device; mapping, based on the name, the output signal to a controller device in a real world environment; and executing a computer model to perform the HIL simulation, wherein the HIL simulation comprises generating the output signal and providing the output signal to the controller device based on mapping the output signal to the controller device.

In some implementations, a system includes a controller; and an HIL simulation platform configured to: analyze a first graphical representation of a device of an operator console; determine, based on analyzing the first graphical representation of the device, device type information and signal information of the device, wherein the device type information identifies a device type of the device, and wherein the signal information identifies one or more types of signals associated with the device; generate, based on the device type information, a second graphical representation of the device for an HIL simulation of an operation of the device; generate, based on the signal information, an output signal from the second graphical representation of the device, wherein the output signal is generated as part of the HIL simulation; and provide the output signal to the controller as part of the HIL simulation.

In some implementations, a non-transitory computer-readable medium storing a set of instructions includes one or more instructions that, when executed by one or more processors of a device, cause the device to: determine device type information and signal information of a device of an operator console based on a two-dimensional representation of a device of an operator console, wherein the device type information identifies a device type of the device, and wherein the signal information identifies signal types of signals associated with the device; generate, based on the device type information, a three-dimensional representation of the device for an HIL simulation of an operation of the device; generate, based on the signal information, an output signal from the three-dimensional representation of the device, wherein the output signal is generated as part of the HIL simulation; and provide the output signal to a controller device as part of the HIL simulation.

### BRIEF DESCRIPTION OF THE DRAWINGS

FIGS. 1A-1E are diagrams of an example implementation described herein.

FIG. 2 is a diagram of an example environment in which systems and/or methods described herein may be implemented.

FIG. 3 is a diagram of example components of one or more devices of FIG. 2.

FIG. 4 is a flowchart of an example process relating to automatically generating simulation devices for an HIL simulation.

### DETAILED DESCRIPTION

The following detailed description of example implementations refers to the accompanying drawings. The same reference numbers in different drawings may identify the same or similar elements.

An HIL simulation involves simulating multiple systems, of a real-time controlled environment, to provide realistic inputs to a controller (e.g., an embedded system) that is being developed or is being tested (e.g., evaluated). A computer model, that models a behavior of the multiple systems and/or the controller, may be executed to cause the HIL simulation to be executed. Each system (e.g., external system) that communicates with the controller is implemented by a mathematical representation (e.g., a software application) that produces signals and values that emulate the real-time controlled environment.

In some situations, an operation of an operator console may be modeled using an HIL simulation. Typically, the operator console is populated with devices that provide the necessary inputs to drive actions in a control system. Such necessary inputs are frequently required as inputs to the HIL simulation of the operation of the operator console.

Currently, the operator console is modeled manually using a software and a computing device. For example, two-dimensional (2D) graphical representations of the devices are manually generated as computer-aided design (CAD) drawings. The CAD drawings are then used as references for manually generating graphical representations of the devices for the HIL simulation.

The graphical representations of the devices (generated for the HIL simulation) may be manually selected and are manually combined to generate a graphical representation of the operator console for the HIL simulation. For example, the graphical representations of the devices (generated for the HIL simulation) are manually connected to the model of the operator console by matching each signal (of the graphical representations of the devices) to the HIL simulation. For instance, each signal is matched to an output and/or an input of the controller included in the HIL simulation.

The process for using a computing device to manually generate the graphical representations of the devices and to manually match signals to an output and/or an input of the controller is a tedious process that is subject to human errors. The human errors may cause considerable delays and require considerable troubleshooting time (or debug time).

Typically, a period of time of approximately one week is allocated to the process. The human errors may include using an incorrect or incompatible device for the operator console. The human errors may further include connecting a signal (of a graphical representation of a device) to an incorrect output or to an incorrect input of the controller.

As a result of the human errors, the HIL simulation may malfunction and/or outputs of the HIL simulation may be inaccurate or inconsistent. The HIL simulation malfunction and/or the outputs being inaccurate or inconsistent may cause troubleshooting of the graphical representations and/or the HIL simulation. The troubleshooting is performed using a computing device and may be a time-consuming process.

Accordingly, the troubleshooting may consume a considerable amount of computing resources used to perform computations associated with the troubleshooting). Additionally, or alternatively, the troubleshooting may consume a considerable amount of network resources used to transmit data regarding the troubleshooting. Additionally, or alternatively, the troubleshooting may consume a considerable amount of storage resources used to store the data regarding the troubleshooting.

Implementations described herein are directed to improving the process of an HIL simulation involving an operator console that includes devices. The devices may include input devices and/or output devices. The process (of the HIL simulation) is improved by significantly reducing the amount of time allocated for the process and improving an accuracy of the process, thereby reducing or eliminating any troubleshoot associated with the process. For example, implementations described herein are directed to automatically generating simulation devices based on CAD drawings of the devices, automatically mapping output signals from the simulation devices to a controller, and automatically mapping input signals from the controller to the simulation devices.

The simulation devices may be automatically generated based on tagged information of the CAD drawings (e.g., tagged information included in the CAD drawings files). The simulation devices may automatically be generated using a machine learning model trained to analyze the CAD drawings and generate the simulation devices based on a result of analyzing the CAD drawings.

A “simulation device” may refer to a graphical representation of a device of the operator console. The graphical representation may be generated based on a CAD drawing of the device for the HIL simulation (e.g., based on a CAD drawing file of the device). In some examples, the graphical representation may be a three-dimensional (3D) graphical representation generated based on a 2D graphical representation of the device (e.g., a CAD drawing the device).

In some examples, the CAD drawing may include information regarding the device. For instance, the CAD drawing may be tagged with the information regarding the device. The information may be used to automatically determine a device type of the device, to automatically determine a signal type of a signal associated with the device, to automatically generate a simulation device of the device, and/or to automatically generate a name of the signal of the simulation device that is to be mapped to the HIL simulation.

As an example, the device type may indicate that the device type (of the device) is a button, a thumbwheel, a switch, a buzzer, and/or a spring-loaded device, among other examples. The information regarding the device may indicate dimensions of the device, a location of the device on the operator console, a visual attribute of the device, among other information that may be used to generate the simulation device. The location may include coordinates of the device on the operator console (e.g., x and y coordinates). The visual attribute may refer to a color generated when the device is illuminated based on an input signal. In this regard, implementations described herein may analyze the CAD drawing to identify the tagged information and use the tagged information to generate the simulation device.

The signal type may indicate that the device has been configured to provide an output signal and/or has been configured to receive an input signal. In some examples, the name of the signal may be determined based on an identifier of the device (e.g., a name of the device) and/or based on the signal type of the signal. For instance, the name of an output signal may be generated using the identifier of the device and an indication that the signal is an output signal.

The signal may be automatically mapped to the HIL simulation (e.g., based on the signal type of the signal and/or based on the name of the signal). For example, an output signal (of the simulation device) may be mapped to an input of the controller. Similarly, an input signal (of the simulation device) may be mapped to an output of the controller.

Additionally, or alternatively to generating the simulation device based on the tagged information, implementations may generate the simulation device using a computer vision model (e.g., without the tagged information). The computer vision model may be a machine learning model trained to recognize (or detect) devices in CAD drawings, determine information regarding the recognized (or detected devices), and generate simulation devices based on the information regarding the recognized (or detected devices).

For example, the computer vision model may be trained using training data that includes documentation regarding the devices. The documentation may be provided by manufacturers of the devices. The training data may train the computer vision model to recognize different devices (of the operator console) and to map input signals and output signals of the devices to the HIL simulation.

In some examples, the computer vision model may be trained to generate 3D graphical representations of the devices from 2D graphical representations of the devices depicted in the CAD drawings. Additionally, or alternatively, the computer vision model may be trained to appropriately route the signals from the devices during the HIL simulation.

In some examples, the computer vision model may generate a configuration file with configuration information regarding the operator console and/or the devices. The information may identify device types of devices included in the operator console, signal types of signals associated with the devices, a manner for routing the signals during an HIL simulation, locations of the devices on the operator console, and/or visual attributes of the devices, among other examples. The configuration file may be used by a software program to generate simulation devices of the devices and to route the signals during the HIL simulation.

Automatically generating the simulation devices and automatically mapping the signals (associated with the simulation devices) to the HIL simulation significantly reduces the amount of time that would have been expanded to use a computing device to manually generate the simulation devices and mapping the signals associated with the simulation devices. For example, the amount of time may be reduced from approximately one week to approximately one day.

Additionally, or alternatively, automatically generating the simulation devices and automatically mapping the signals associated with the simulation devices reduces or eliminates human errors resulting from manually generating the simulation devices and mapping the signals. The human errors are reduced or eliminated by requiring no human intervention. Accordingly, implementations described herein prevent the HIL simulation from malfunctioning and enable accurate and consistent results of the HIL simulation.

Therefore, implementations described herein reduce or eliminate troubleshooting of the simulation devices, of the signals associated with the simulation devices, and/or of the HIL simulation. Accordingly, implementations described herein preserve computing resources, network resources, and/or storage resources that would have been used during the troubleshooting.

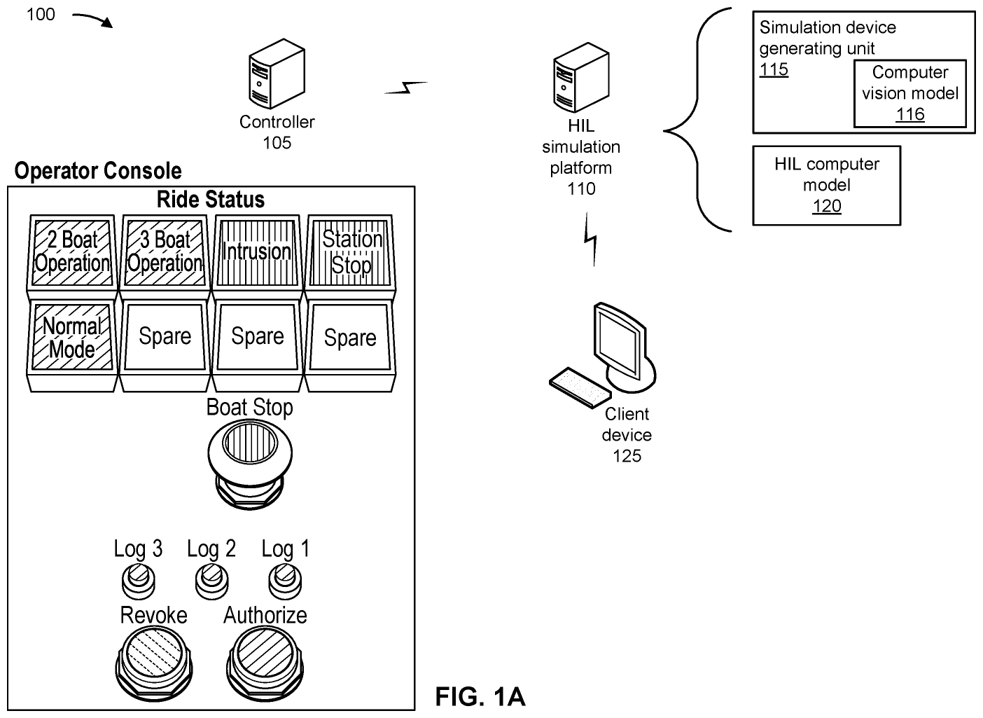

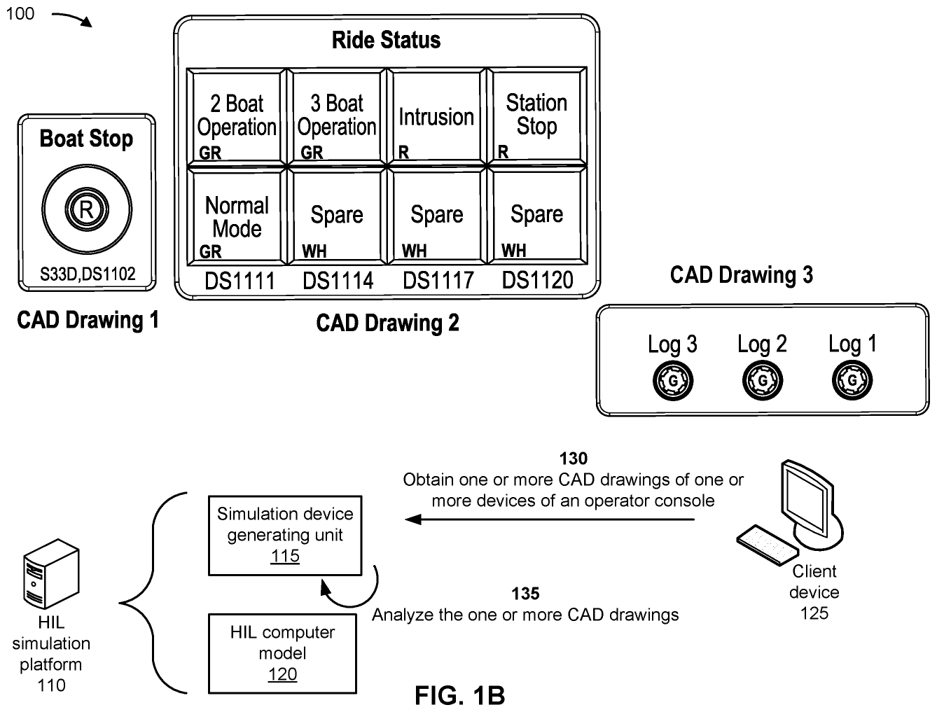

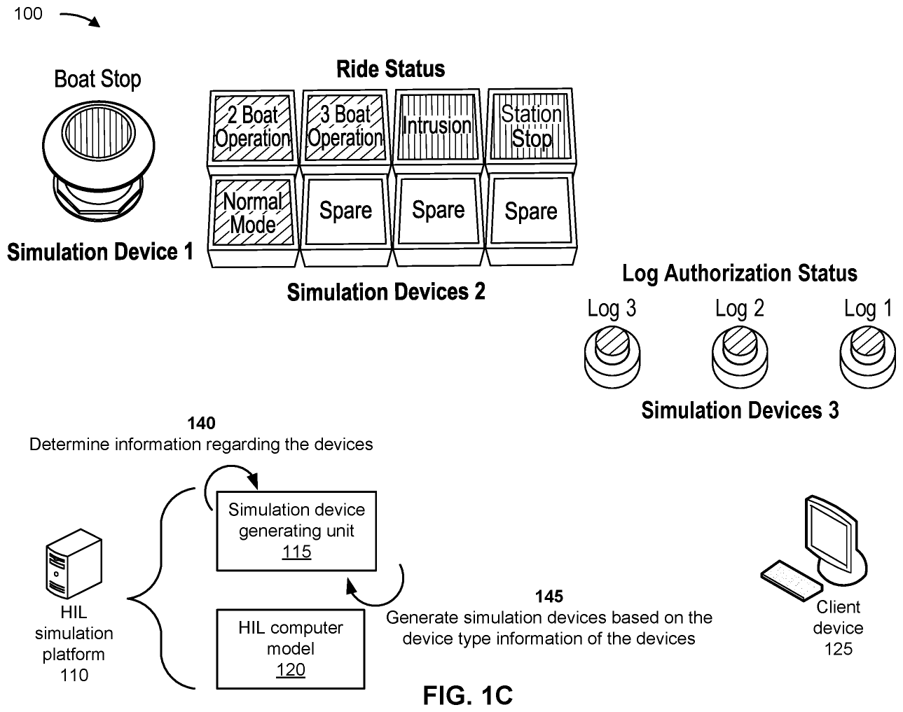

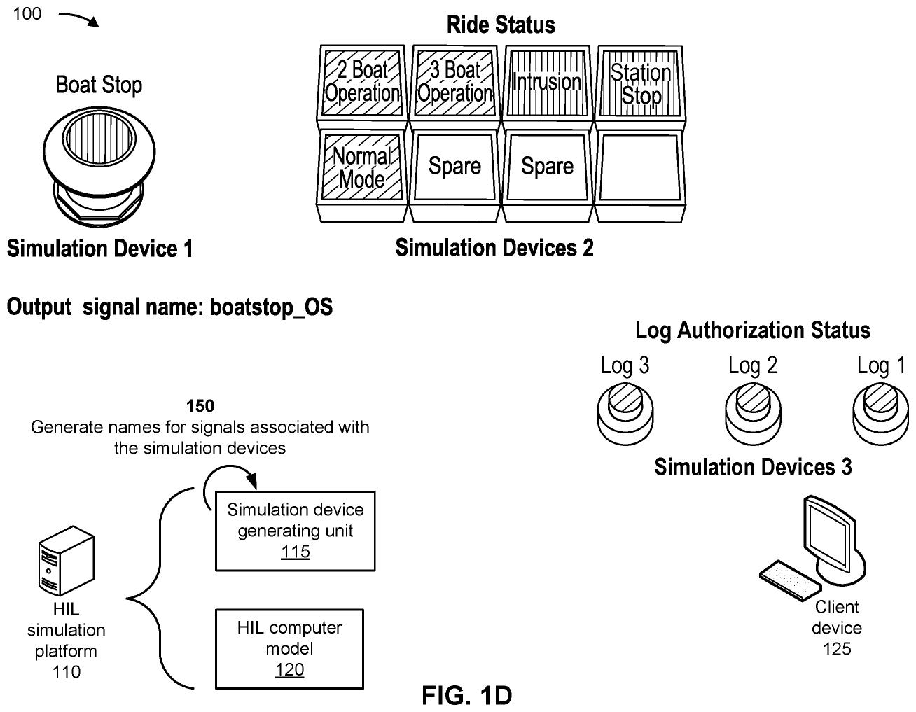

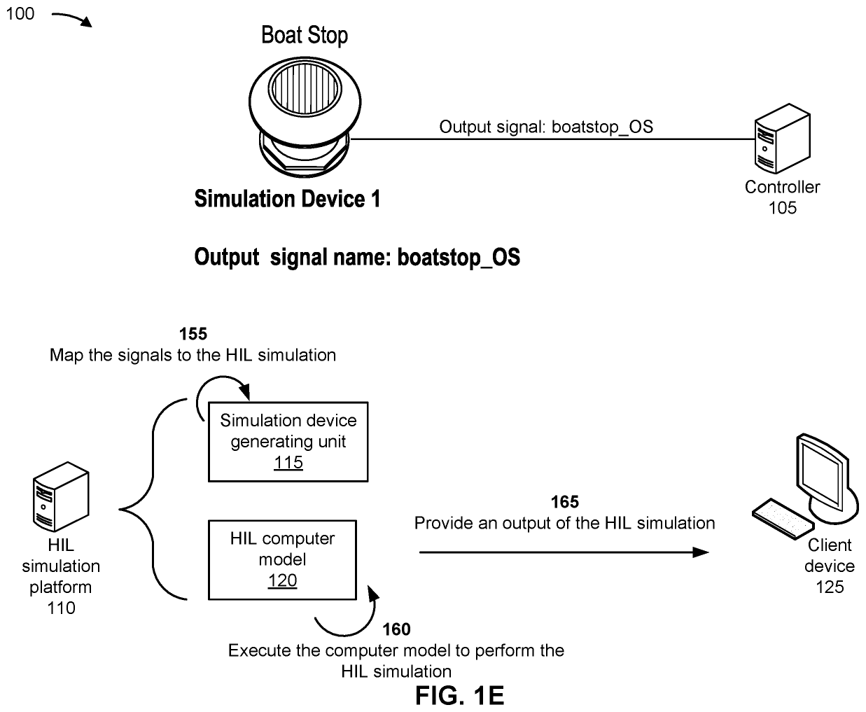

FIGS. 1A-1E are diagrams of an example implementation 100 associated with automatically generating simulation devices for an HIL simulation. As shown in FIGS. 1A-1E, example implementation 100 includes a controller 105, an HIL simulation platform 110, and a client device 125. Controller 105 may include one or more devices configured to control operations of multiples systems or devices of different industries (e.g., automotive, manufacturing, healthcare, mining, construction, farming, transportation, and/or amusement parks, among other examples). In some situations, controller 105 may provide multiple inputs (e.g., thousands of inputs) to the systems to control the systems.

In the context of amusement parks as an example, the systems or devices may include components of a ride system and/or of a show system, such as passenger vehicles, location sensors, speed sensors, brake systems, motors, animatronic equipment, and/or lighting equipment, among other examples. In some implementations, controller 105 may include a programmable logic controller (PLC). In some situations, the PLC may be referred to as a wayside ride control system (WRCS).

Controller 105 may be utilized during an HIL simulation. In this regard, during the HIL simulation, controller 105 may receive output signals from simulation devices of the HIL simulation. Additionally, or alternatively, controller 105 may provide input signals to the simulation devices during the HIL simulation.

HIL simulation platform 110 may include one or more devices configured to host an HIL simulation environment. As shown in FIG. 1A, HIL simulation platform 110 may include a simulation device generating unit 115 and an HIL computer model 120. Simulation device generating unit 115 may be configured to automatically generate simulation devices of devices of an operator console and to automatically map signals of the simulation devices to an HIL simulation of an operation of the operator console.

In some implementations, simulation device generating unit 115 may be configured to analyze a CAD drawing to identify tagged information of the CAD drawing. As an example, the tagged information may be metadata of the CAD drawing. Simulation device generating unit 115 may use the tagged information the CAD drawing to automatically generate a simulation device of a device depicted by the CAD drawing, to automatically generate names of signals associated with the simulation device, and to automatically map the signals to the HIL simulation.

In some implementations, simulation device generating unit 115 may include a computer vision model 116. Computer vision model 116 may be a machine learning model trained using training data that includes documentation regarding devices of operator consoles. The documentation may be provided by manufacturers of the devices. As an example, the documentation may include a catalog of the devices.

As an example, the documentation for a device may depict the device. Additionally, or alternatively, the documentation may include an identifier of the device, information identifying a device type of the device, information identifying dimensions of the device, information identifying a location of the device on the operator console, information identifying a visual attribute of the device, information identifying a style of the device, information identifying a functionality of the device, and/or information identifying signal types of signals associated with the device, among other examples.

The identifier of the device may include a name of the device, a part number of the device, a serial number of the device, among other examples. The style of the device may indicate whether the device is a press button, a two-position button, and/or a three-position button, among other examples. The functionality of the device may indicate whether the device is a normally-open device or a normally-closed device.

Accordingly, computer vision model 116 may be trained to recognize the device in a CAD drawing using the training data (e.g., the depiction of the device). Additionally, or alternatively, computer vision model 116 may be trained to generate the simulation device using the training data (e.g., using the dimensions of the device, the visual attribute of the device, the style of the device, the functionality of the device, and/or the location of the device, among other examples).

Additionally, or alternatively, computer vision model 116 may be trained to generate names of signals associated with the device (e.g., using the identifier of the device and/or the signal types of the signals associated with the device). Additionally, or alternatively, computer vision model 116 may be trained to the signals to the HIL simulation (e.g., using the identifier of the device and/or the signal types of the signals associated with the device).

In some implementations, computer vision model 116 may be trained by HIL simulation platform 110. Additionally, or alternatively, computer vision model 116 may be trained another by another device and may be subsequently provided to HIL simulation platform 110.

Computer vision model 116 may implement one or more object recognition techniques. For example, computer vision model 116 may implement a convolutional neural network (CNN), a Single Shot MultiBox Detector (SSD) technique, and/or a You Only Look Once (YOLO) technique, among other examples.

The HIL computer model 120 may include a computer model that is executed to a launch the HIL simulation. For example, HIL simulation platform 110 may be configured to execute HIL computer model 120 to launch the HIL simulation.

Client device 125 may include one or more devices capable of receiving, generating, storing, processing, and/or providing information associated with automatically generating simulation devices for an HIL simulation. Additionally, or alternatively, client device 125 may be capable of receiving (e.g., from HIL simulation platform 110) outputs of HIL simulations (e.g., numerous outputs) and provide the outputs for display (e.g., to a modeler of HIL computer model 120, to an individual associated with client device 125, among other examples). In some implementations, client device 125 may include simulation device generating unit 115. Additionally, or alternatively, client device 125 may be configured to execute HIL computer model 120 in a manner similar to a manner in which HIL simulation platform 110 executes HIL computer model 120.

As shown in FIG. 1B, and by reference number 130, HIL simulation platform 110 may obtain one or more CAD drawings of one or more devices of an operator console. For example, HIL simulation platform 110 may obtain the one or more CAD drawings as one or more files (e.g., in an electronic format). In some implementations, HIL simulation platform 110 may obtain the one or more CAD drawings from client device 125. For example, client device 125 may provide the one or more CAD drawings along with a request to automatically generate simulation devices and to automatically map signals of the simulation devices to an HIL simulation involving the operator console.

In some implementations, HIL simulation platform 110 may obtain the one or more CAD drawings from a repository of CAD drawings. For example, HIL simulation platform 110 may obtain the one or more CAD drawings based on a trigger (e.g., based on the request from client device 125).

As shown in FIG. 1B, HIL simulation platform 110 may obtain CAD drawing 1, CAD drawing 2, and/or CAD drawing 3. CAD drawing 1 depicts a device for controlling an operation of a boat. CAD drawing 2 depicts devices that provide a status of a ride of an amusement park. CAD drawing 3 depicts devices that provide a status regarding log authorization.

As shown in FIG. 1B, and by reference number 135, HIL simulation platform 110 may analyze the one or more CAD drawings. For example, HIL simulation platform 110 may analyze the one or more CAD drawings to determine information that may be used to automatically generate simulation devices and to automatically map signals (e.g., associated with the simulation devices) to the HIL simulation.

In some implementations, simulation device generating unit 115 may analyze the one or more CAD drawings to determine tagged information regarding the devices. For example, simulation device generating unit 115 may analyze CAD drawing 1 to determine tagged information regarding a particular device depicted in CAD drawing 1. The tagged information may be metadata that includes information regarding the particular device.

In some implementations, simulation device generating unit 115 may analyze the one or more CAD drawings using computer vision model 116. For example, computer vision model 116 may be used to analyze CAD drawing 1 to recognize the particular device depicted in CAD drawing 1.

As shown in FIG. 1C, and by reference number 140, HIL simulation platform 110 may determine information regarding the devices. For example, based on analyzing the one or more CAD drawings, HIL simulation platform 110 may determine the information regarding the devices.

In some implementations, simulation device generating unit 115 may determine the information regarding the devices based on the tagged information regarding the devices. For example, simulation device generating unit 115 may determine the information regarding the particular device based on metadata of CAD drawing 1. For instance, the metadata may include the information regarding the particular device.

The information regarding the particular device may include an identifier of the particular device, device type information identifying a type of the particular device, information identifying dimensions of the particular device, information identifying a location of the particular device on the operator console, information identifying a visual attribute of the particular device, information identifying a style of the particular device, information identifying a functionality of the particular device, and/or signal type information identifying signal types of signals associated with the particular device, among other examples. Simulation device generating unit 115 may determine the information regarding other devices depicted in other CAD drawings in a similar manner.

In some implementations, simulation device generating unit 115 determine the information regarding the particular device using computer vision model 116. For example, computer vision model 116 may recognize (or detect) the particular device depicted in CAD drawing 1 and, accordingly, determine the information regarding the particular device. Computer vision model 116 may recognize the particular device and determine the information regarding the particular device based on computer vision model 116 being trained with training data depicting the particular device and with tagged information included in the depiction and/or provided with the depictions. Simulation device generating unit 115 may use computer vision model 116 to determine the information regarding other devices depicted in other CAD drawings in a similar manner.

As shown in FIG. 1C, and by reference number 145, HIL simulation platform 110 may generate simulations devices based on the device type information of the devices. For example, after determining the device information regarding the particular device, simulation device generating unit 115 may generate computer code that is executed to generate a simulation device for the particular device. In some implementations, simulation device generating unit 115 may generate the simulation device based on the device type information of the particular device. For example, if the device type information indicates that the particular device is a switch, simulation device generating unit 115 may generate a simulation device that is a switch; if the device type information indicates that the particular device is a thumbwheel, simulation device generating unit 115 may generate a simulation device that is a thumbwheel; and so on.

Additionally, or alternatively, simulation device generating unit 115 may generate the simulation device based on information identifying dimensions of the particular device information identifying a location of the particular device on the operator console, information identifying a visual attribute of the particular device, information identifying a style of the particular device, information identifying a functionality of the particular device.

For example, simulation device generating unit 115 may cause dimensions of the simulation device to be proportional to the dimensions of the particular device. In some situations, the dimensions of the particular device and/or other information included in the information regarding the particular device may be used to generate a 3D rendering of the particular device. Additionally, or alternatively, simulation device generating unit 115 may provide the simulation device on a representation of the operator console at a location corresponding to the location of the particular device. Additionally, or alternatively, simulation device generating unit 115 may generate the simulation device to include the visual attribute of the particular device. For example, if an input signal cause the particular device to be illuminated in accordance with a particular color, simulation device generating unit 115 may cause the simulation device to be illuminated in a similar manner based on receiving an input signal during the HIL simulation.

Additionally, or alternatively, if the style indicates that the particular device is a particular type of button (e.g., a press button, a two-position button, a three-position button), simulation device generating unit 115 may generate the simulation device to be the particular type of button. Additionally, or alternatively, if the functionality indicates that the particular device is a normally-open device or a normally-closed device, simulation device generating unit 115 may generate the simulation device to be a normally-open device or a normally-closed device.

As shown in FIG. 1C, simulation device generating unit 115 may generate simulation device 1 for the particular device depicted in CAD drawing 1, generate simulation devices 2 for the devices depicted in CAD drawing 2, and/or generate simulation devices 2 for the devices depicted in CAD drawing 2.

As shown in FIG. 1D, and by reference number 150, HIL simulation platform 110 may generate names for signals associated with the simulation devices. For example, simulation device generating unit 115 may generate names for output signals from and for input signals to the simulation devices. In some implementations, HIL simulation platform 110 may generate the names of the signals based on the information regarding the devices. For example, simulation device generating unit 115 may generate the names of the signals based on the identifiers of the devices and/or based on the signal type information identifying the signal types of the signals.

As an example, if the identifier of the particular device (depicted in CAD drawing 1) is Boat Stop and if the signal type is an output signal, simulation device generating unit 115 may generate a name of “boatstop_OS” (with “boatstop” being indicative the identifier of the particular device and with “OS” being indicative of an output signal). Similarly, if the identifier of the particular device (depicted in CAD drawing 1) is Boat Stop and if the signal type is an input signal, simulation device generating unit 115 may generate a name of “boatstop_IS.” Simulation device generating unit 115 may generate the names of other signals in a similar manner.

As shown in FIG. 1E, and by reference number 155, HIL simulation platform 110 may map the signals to the HIL simulation. For example, simulation device generating unit 115 may map output signals from the simulation devices to an input of controller 105 and may map input signals from an output of controller 105 to the simulation devices. In some implementations, simulation device generating unit 115 may use the names of the signals to map the signals to controller 105.

For example, simulation device generating unit 115 may map a signal with a name indicating an output signal to an input of controller 105 and may map a signal with a name indicating an input signal to an input of an appropriate simulation device. As an example, simulation device generating unit 115 may map the signal with the name “boatstop_OS” from simulation device 1 to the input of controller 105. In this regard, during the HIL simulation, the signal with the name “boatstop_OS” may be provided to the input of controller 105.

In some implementations, the signal type information of a signal may identify attributes associated with the signal, such as a magnitude of the signal, a range of values for the signal, a threshold associated with the signal, a threshold associated with the signal, a manner of processing a fault associated with transmitting and/or receive the signal, among other examples. In this regard, the signal from the simulation device may be subject to with the name “boatstop_OS” may subject to the attributes during the HIL simulation.

As shown in FIG. 1E, and by reference number 160, HIL simulation platform 110 may execute the computer model to perform the HIL simulation. For example, after mapping the signals to the HIL simulation, HIL simulation platform 110 may execute HIL computer model 120 to perform the HIL simulation. During the HIL simulation, the simulation devices may generate output signals that are provided to the input of controller 105 based on the output signals being mapped to the input of controller 105. Conversely, the simulation devices may receive input signals that are generated by controller 105 based on the input signals being mapped to the output of controller 105.

As shown in FIG. 1E, and by reference number 165, HIL simulation platform 110 may provide an output of the HIL simulation. For example, HIL simulation platform 110 may provide the output of the HIL simulation to client device 125. In some implementations, the output of the HIL simulation may be a visualization of the HIL simulation. For example, the output of the HIL simulation may provide a visualization of the simulation devices, the signals exchanged between the simulation devices and controller 105, and/or actions performed by the simulation devices (e.g., the simulation devices being illuminated, being depressed, among other examples).

Implementations described herein reduce the amount of time that would have been expanded to use a computing device to manually generate the simulation devices and mapping the signals associated with the simulation devices. Additionally, or alternatively, implementations described herein reduces or eliminates human errors resulting from manually generating the simulation devices and mapping the signals. Accordingly, implementations described herein prevent the HIL simulation from malfunctioning and enable accurate and consistent results of the HIL simulation.

Therefore, implementations described herein reduce or eliminate troubleshooting of the simulation devices, of the signals associated with the simulation devices, and/or of the HIL simulation. Accordingly, implementations described herein preserve computing resources, network resources, and storage resources that would have been used during the troubleshooting.

As indicated above, FIGS. 1A-1E are provided as an example. Other examples may differ from what is described with regard to FIGS. 1A-1E. The number and arrangement of devices shown in FIGS. 1A-1E are provided as an example. In practice, there may be additional devices, fewer devices, different devices, or differently arranged devices than those shown in FIGS. 1A-1E. Furthermore, two or more devices shown in FIGS. 1A-1E may be implemented within a single device, or a single device shown in FIGS. 1A-1E may be implemented as multiple, distributed devices. Additionally, or alternatively, a set of devices (e.g., one or more devices) shown in FIGS. 1A-1E may perform one or more functions described as being performed by another set of devices shown in FIGS. 1A-1E.

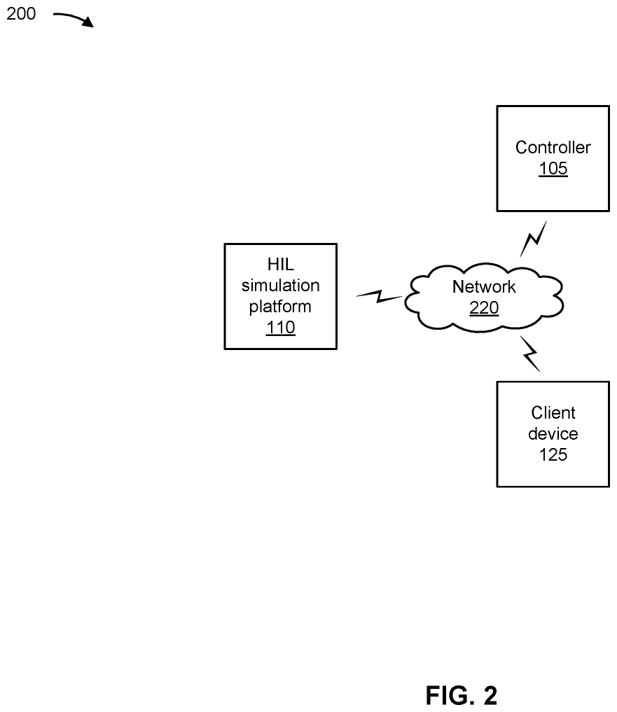

FIG. 2 is a diagram of an example environment 200 in which systems and/or methods described herein may be implemented. Some elements of environment 200 have been described above in connection with FIG. 1. In some implementations, HIL simulation platform 110 may include one or more elements of and/or may execute within a cloud computing system. As further shown in FIG. 2, environment 200 may include controller, client device 125, and/or a network 220. Devices and/or elements of environment 200 may interconnect via wired connections and/or wireless connections.

In some situations, HIL simulation platform 110 may be implemented on a server, such as an application server, a client server, a web server, a database server, a host server, a proxy server, a virtual server (e.g., executing on computing hardware), or a server in a cloud computing system. In some implementations, HIL simulation platform 110 implemented on using computing hardware used in a cloud computing environment.

Client device 125 includes one or more devices capable of receiving, generating, storing, processing, and/or providing information associated with configuring a launch of software components. Client device 125 may include a communication device and a computing device. For example, client device 125 may include a wireless communication device, a mobile phone, a user equipment, a laptop computer, a tablet computer, a desktop computer, or a similar type of device.

Network 220 includes one or more wired and/or wireless networks. For example, network 220 may include a cellular network, a public land mobile network (PLMN), a local area network (LAN), a wide area network (WAN), a private network, the Internet, and/or a combination of these or other types of networks. The network 220 enables communication among the devices of environment 200.

The number and arrangement of devices and networks shown in FIG. 2 are provided as an example. In practice, there may be additional devices and/or networks, fewer devices and/or networks, different devices and/or networks, or differently arranged devices and/or networks than those shown in FIG. 2. Furthermore, two or more devices shown in FIG. 2 may be implemented within a single device, or a single device shown in FIG. 2 may be implemented as multiple, distributed devices. Additionally, or alternatively, a set of devices (e.g., one or more devices) of environment 200 may perform one or more functions described as being performed by another set of devices of environment 200.

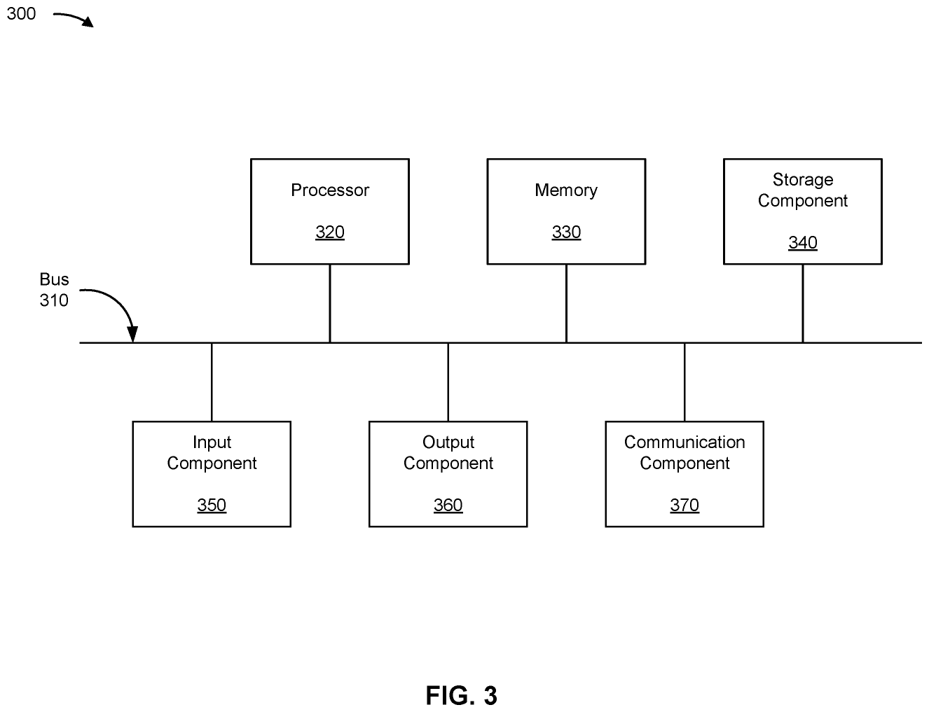

FIG. 3 is a diagram of example components of a device 300, which may correspond to HIL simulation platform 110, controller 105, and/or client device 125. In some implementations, HIL simulation platform 110, controller 105, and/or client device 125 may include one or more devices 300 and/or one or more components of device 300. As shown in FIG. 3, device 300 may include a bus 310, a processor 320, a memory 330, a storage component 340, an input component 350, an output component 360, and a communication component 370.

Bus 310 includes a component that enables wired and/or wireless communication among the components of device 300. Processor 320 includes a central processing unit, a graphics processing unit, a microprocessor, a controller, a microcontroller, a digital signal processor, a field-programmable gate array, an application-specific integrated circuit, and/or another type of processing component. Processor 320 is implemented in hardware, firmware, or a combination of hardware and software. In some implementations, processor 320 includes one or more processors capable of being programmed to perform a function. Memory 330 includes a random access memory, a read only memory, and/or another type of memory (e.g., a flash memory, a magnetic memory, and/or an optical memory).

Storage component 340 stores information and/or software related to the operation of device 300. For example, storage component 340 may include a hard disk drive, a magnetic disk drive, an optical disk drive, a solid state disk drive, a compact disc, a digital versatile disc, and/or another type of non-transitory computer-readable medium. Input component 350 enables device 300 to receive input, such as user input and/or sensed inputs. For example, input component 350 may include a touch screen, a keyboard, a keypad, a mouse, a button, a microphone, a switch, a sensor, a global positioning system component, an accelerometer, a gyroscope, and/or an actuator. Output component 360 enables device 300 to provide output, such as via a display, a speaker, and/or one or more light-emitting diodes. Communication component 370 enables device 300 to communicate with other devices, such as via a wired connection and/or a wireless connection. For example, communication component 370 may include a receiver, a transmitter, a transceiver, a modem, a network interface card, and/or an antenna.

Device 300 may perform one or more processes described herein. For example, a non-transitory computer-readable medium (e.g., memory 330 and/or storage component 340) may store a set of instructions (e.g., one or more instructions, code, software code, and/or program code) for execution by processor 320. Processor 320 may execute the set of instructions to perform one or more processes described herein. In some implementations, execution of the set of instructions, by one or more processors 320, causes the one or more processors 320 and/or the device 300 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 3 are provided as an example. Device 300 may include additional components, fewer components, different components, or differently arranged components than those shown in FIG. 3. Additionally, or alternatively, a set of components (e.g., one or more components) of device 300 may perform one or more functions described as being performed by another set of components of device 300.

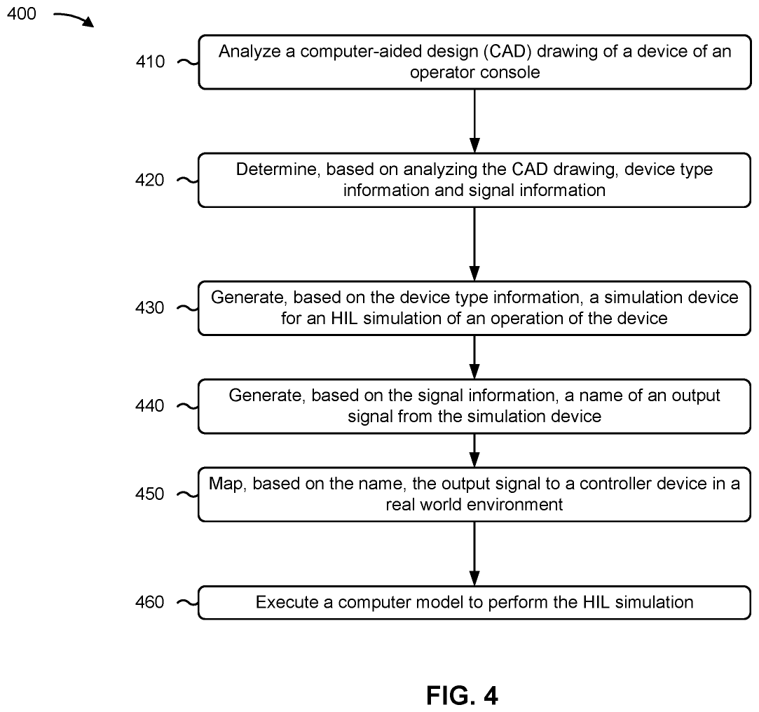

FIG. 4 is a flowchart of an example process 400 relating to automatically generating simulation devices for an HIL simulation. In some implementations, one or more process blocks of FIG. 4 may be performed by an HIL simulation platform (e.g., simulation device generating unit 115 of HIL simulation platform 110). In some implementations, one or more process blocks of FIG. 4 may be performed by another device or a group of devices separate from or including the launcher application of the HIL simulation platform, such as a controller (e.g., controller 105) and/or by a client device (e.g., client device 125). Additionally, or alternatively, one or more process blocks of FIG. 4 may be performed by one or more components of device 300, such as processor 320, memory 330, storage component 340, input component 350, output component 360, and/or communication component 370.

As shown in FIG. 4, process 400 may include analyzing a computer-aided design (CAD) drawing of a device of an operator console (block 410). For example, the HIL simulation platform may analyze a computer-aided design (CAD) drawing of a device of an operator console. In some implementations, the CAD drawing is a two-dimensional representation of the device.

As further shown in FIG. 4, process 400 may include determining, based on analyzing the CAD drawing, device type information and signal information of the device (block 420). For example, the HIL simulation platform may determine, based on analyzing the CAD drawing, device type information and signal information of the device. In some implementations, the device type information identifies a device type of the device. The signal information identifies one or more signal types of signals associated with the device.

In some implementations, the device type information identifies dimensions of the device. In some examples, determining the device type information and the signal information comprises obtaining the device type information and the signal information from one or more data tags of the CAD drawing.

In some implementations, determining the device type information and the signal information comprises analyzing the CAD drawing using a machine learning model. The machine learning model may be trained to determine device types of devices depicted in CAD drawings and trained to determine signal types of signals associated with the devices. In some examples, the device type information and the signal information are determined using the machine learning model.

In some implementations, process 400 includes determining, based on the device type information, one or more of a visual attribute of the device, or a location of the device on the operator console, wherein generating the simulation device comprises at least one of causing the simulation device to be depicted with the visual attribute, or causing the simulation device to be provided, on a representation of the operator console, at a location corresponding to the location of the device.

As further shown in FIG. 4, process 400 may include generating, based on the device type information, a simulation device for an HIL simulation of an operation of the device in an HIL simulation environment (block 430). For example, the HIL simulation platform may generate, based on the device type information, a simulation device for an HIL simulation of an operation of the device in an HIL simulation environment. In some implementations, generating the simulation device comprises generating a three-dimensional representation of the device based on the dimensions of the device.

As further shown in FIG. 4, process 400 may include generating, based on the signal information, a name of an output signal from the simulation device (block 440). For example, the HIL simulation platform may generate, based on the signal information, a name of an output signal from the simulation device.

As further shown in FIG. 4, process 400 may include mapping, based on the name, the output signal to a controller device in a real world environment (block 450). For example, the HIL simulation platform may map, based on the name, the output signal to a controller device in a real world environment.

As further shown in FIG. 4, process 400 may include executing a computer model to perform the HIL simulation (block 460). For example, the HIL simulation platform may execute a computer model to perform the HIL simulation. In some implementations, the HIL simulation comprises generating the output signal and providing the output signal to the controller device based on mapping the output signal to the controller device.

In some implementations, executing the computer model to perform the HIL simulation further comprises receiving an input signal from the controller device based on providing the output signal, and causing the simulation device to perform an action in the HIL simulation environment.

In some implementations, providing the output signal to the controller device comprises providing the output signal to the controller device to cause the controller device to generate a command that controls a system.

Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

The foregoing disclosure provides illustration and description, but is not intended to be exhaustive or to limit the implementations to the precise forms disclosed. Modifications may be made in light of the above disclosure or may be acquired from practice of the implementations.

As used herein, the term “component” is intended to be broadly construed as hardware, firmware, or a combination of hardware and software. It will be apparent that systems and/or methods described herein may be implemented in different forms of hardware, firmware, and/or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be used to implement the systems and/or methods based on the description herein.

Although particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method performed by a hardware-in-the-loop (HIL) simulation platform, the method comprising:
analyzing a computer-aided design (CAD) drawing of a device of an operator console;
determining, based on analyzing the CAD drawing, device type information and signal information of the device,
wherein the device type information identifies a device type of the device, and wherein the signal information identifies one or more signal types of signals associated with the device;
generating, based on the device type information, a simulation device for an HIL simulation of an operation of the device in an HIL simulation environment;
generating, based on the signal information, a name of an output signal from the simulation device;
mapping, based on the name, the output signal to a controller device in a real world environment; and
executing a computer model to perform the HIL simulation,
wherein the HIL simulation comprises generating the output signal and providing the output signal to the controller device based on mapping the output signal to the controller device.

2. The method of claim 1, wherein the CAD drawing is a two-dimensional representation of the device,
wherein the device type information further identifies dimensions of the device, and
wherein generated the simulation device comprises:
generating a three-dimensional representation of the device based on the dimensions of the device.

3. The method of claim 1, wherein determining the device type information and the signal information comprises:
obtaining the device type information and the signal information from one or more data tags of the CAD drawing.

4. The method of claim 1, wherein determining the device type information and the signal information comprises:
analyzing the CAD drawing using a machine learning model,
wherein the machine learning model is trained to determine device types of devices depicted in CAD drawings and trained to determine signal types of signals associated with the devices; and
determining the device type information and the signal information using the machine learning model.

5. The method of claim 1, wherein executing the computer model to perform the HIL simulation further comprises:
receiving an input signal from the controller device based on providing the output signal; and
causing the simulation device to perform an action in the HIL simulation environment.

6. The method of claim 1, further comprising:
determining, based on the device type information, one or more of:
a visual attribute of the device, or
a location of the device on the operator console,
wherein generating the simulation device comprises at least one of:
causing the simulation device to be depicted with the visual attribute, or
causing the simulation device to be provided, on a representation of the operator console, at a location corresponding to the location of the device.

7. The method of claim 1, wherein providing the output signal to the controller device comprises:
providing the output signal to the controller device to cause the controller device to generate a command that controls a system.

8. A system, comprising:
a controller; and
a hardware-in-the-loop (HIL) simulation platform configured to:
analyze a first graphical representation of a device of an operator console;
determine, based on analyzing the first graphical representation of the device, device type information and signal information of the device,
wherein the device type information identifies a device type of the device, and wherein the signal information identifies one or more types of signals associated with the device;
generate, based on the device type information, a second graphical representation of the device for an HIL simulation of an operation of the device;
generate, based on the signal information, an output signal from the second graphical representation of the device,
wherein the output signal is generated as part of the HIL simulation; and
provide the output signal to the controller as part of the HIL simulation.

9. The system of claim 8, wherein, to determine the device type information and the signal information, the HIL simulation platform is further configured to:
analyze the first graphical representation using a computer vision model,
wherein the computer vision model is trained to determine device types of devices depicted in graphical representations and trained to determine signals associated with the devices; and
determine the device type information and the signal information based on analyzing the first graphical representation using the computer vision model.

10. The system of claim 9, wherein the HIL simulation platform is further configured to:
train the computer vision model using training data regarding a plurality of devices of operator consoles,
wherein the training data include graphical representations of the plurality of devices and at least one of information identifying a plurality of device types of the plurality of devices, information identifying dimensions of the plurality of devices, information identifying input signals to the plurality of devices, or information identifying output signals from the plurality of devices.

11. The system of claim 9, wherein the HIL simulation platform is further configured to:
determine, using the computer vision model, a manner for routing an input signal from the controller to the second graphical representation of the device during the HIL simulation; and
determine, using the computer vision model, a manner for routing the output signal from the second graphical representation of the device to the controller during the HIL simulation.

12. The system of claim 8, wherein the HIL simulation platform is further configured to:
generate an identifier for the output signal; and
route the output signal to the controller based on the identifier.

13. The system of claim 8, wherein, to generating the first graphical representation of the device, the HIL simulation platform is further configured to:
determine, based on the device type information, that the device type is:
a button,
a switch,
a thumbwheel, or
a buzzer; and
generate, for the HIL simulation, a representation of:
the button,
the switch,
the thumbwheel, or
the buzzer.

14. The system of claim 8, wherein the HIL simulation platform is further configured to:
generate configuration information regarding a plurality of devices of the operator console,
wherein the configuration information identifies one or more device types of the plurality of devices, signal types of signals associated with the plurality of devices, names of the signals, and
wherein the plurality of devices include the device.

15. A non-transitory computer-readable medium storing a set of instructions, the set of instructions comprising:
one or more instructions that, when executed by one or more processors of a device, cause the device to:
determine device type information and signal information of a device of an operator console based on a two-dimensional representation of a device of an operator console,
wherein the device type information identifies a device type of the device, and wherein the signal information identifies signal types of signals associated with the device;
generate, based on the device type information, a three-dimensional representation of the device for an HIL simulation of an operation of the device;
generate, based on the signal information, an output signal from the three-dimensional representation of the device,
wherein the output signal is generated as part of the HIL simulation; and
provide the output signal to a controller device as part of the HIL simulation.

16. The non-transitory computer-readable medium of claim 15, wherein the two-dimensional representation is tagged with a data tag, and
wherein the one or more instructions, that cause the device to determine the device type information and the signal information, cause the device to:
determine the device type information and the signal information based on the data tag.

17. The non-transitory computer-readable medium of claim 15, wherein the one or more instructions, that cause the device to determine the device type information and the signal information, cause the device to:
analyze the two-dimensional representation using a computer vision model,
wherein the computer vision model is trained to determine device types of devices depicted in graphical representations and trained to determine signal types of signals associated with the devices; and
determine the device type information and the signal information based on analyzing the two-dimensional representation using the computer vision model.

18. The non-transitory computer-readable medium of claim 17, wherein the one or more instructions further cause the device to:
determine, using the computer vision model, a manner for routing an input signal from the controller device to the three-dimensional representation of the device during the HIL simulation; and
determine, using the computer vision model, a manner for routing the output signal from the three-dimensional representation of the device to the controller device during the HIL simulation.

19. The non-transitory computer-readable medium of claim 17, wherein the one or more instructions further cause the device to:
generate, based on the signal information, an identifier for the output signal; and
provide the output signal based on the identifier.

20. The non-transitory computer-readable medium of claim 15, wherein the one or more instructions further cause the device to:
generate configuration information regarding a plurality of devices of the operator console,
wherein the configuration information identifies one or more device types of the plurality of devices, signal types of signals associated with the plurality of devices, names of the signals, and
wherein the plurality of devices include the device.
